(19) United States
(12) Patent Application Publication
(10) Pub. No.: US 2026/0188609 A1
(43) Pub. Date: Jul. 2, 2026

(54) ABNORMALITY DIAGNOSIS METHOD FOR BLANKING APERTURE ARRAY SUBSTRATE AND MULTI-BEAM WRITING METHOD

(71) Applicant: NuFlare Technology, Inc., Yokohama-shi (JP)

(72) Inventors: Yoshihisa KAWABATA, Yokohama-shi (JP); Yasuo SENGOKU, Yokohama-shi (JP); Hideo INOUE, Yokohama-shi (JP); Takuya MATSUKAWA, Yokohama-shi (JP); Yusuke YOSHIDA, Yokohama-shi (JP)

(73) Assignee: NuFlare Technology, Inc., Yokohama-shi (JP)

(21) Appl. No.: 19/545,778

(22) Filed: Feb. 20, 2026

Related U.S. Application Data
(63) Continuation of application No. PCT/JP2024/025090, filed on Jul. 11, 2024.

(30) Foreign Application Priority Data
Nov. 24, 2023 (JP) 2023-199281

(51) Int. Cl. H01J 37/244; H01J 37/04; H01J 37/317

(52) U.S. Cl. CPC H01J 37/244; H01J 37/045; H01J 37/3177; H01J 2237/0435; H01J 2237/24578

(57) ABSTRACT

The present invention efficiently and accurately diagnoses abnormalities of blankers. An abnormality diagnosis method for a blanking aperture array substrate according to the present embodiment includes grouping the plurality of individual blankers into a plurality of groups, measuring blanking performance of the individual blankers for each group, and iteratively subdividing any group exhibiting abnormal blanking performance into subgroups to identify an individual blanker having abnormal blanking performance.

### CROSS REFERENCE TO RELATED APPLICATIONS

This application is a continuation of International Application No. PCT/JP2024/025090, filed on Jul. 11, 2024, which claims priority to Japanese Patent Application No. 2023-199281, filed on Nov. 24, 2023, and which is hereby incorporated by reference in its entirety.

### FIELD

The present invention relates to a method for diagnosing abnormalities of a blanking aperture array substrate and to a multi-beam writing method.

### BACKGROUND

With the increase in the integration density of large-scale integrated circuits (LSIs), the required circuit linewidths for semiconductor devices have become finer year by year. In order to form a desired circuit pattern on a semiconductor device, a method is employed in which a high-precision original pattern formed on quartz (a mask, or, in particular, one used in a stepper or scanner, also called a reticle) is reduced and transferred onto a wafer using a reduction-projection exposure apparatus. The high-precision original pattern is written by an electron beam writing apparatus onto a substrate such as a mask blank on which a Cr film and a resist film are formed on a quartz substrate, employing so-called electron beam lithography technology.

For example, there exists a writing apparatus that uses multiple beams. Compared with writing using a single electron beam, the use of multiple beams allows many beams to be irradiated in a single shot, thereby improving throughput. In a multi-beam writing apparatus, blanking control of each beam of the multi-beam (control for shielding the beam so that it does not reach the substrate) is performed by a blanking aperture array substrate.

In the blanking aperture array substrate, multiple apertures corresponding to the respective beams of the multi-beam are formed, and in each aperture, a blanker composed of a pair of electrodes is arranged. By controlling the voltage applied to each blanker, the electron beam passing through each aperture is independently deflected, thereby performing blanking control.

If a blanker has a defect and the desired voltage cannot be applied, the beam can no longer be switched on or off, or cannot be irradiated at the desired position, resulting in degradation of writing accuracy. Therefore, it is necessary to identify the blanker that has the defect.

However, measuring the blanking performance of the blankers individually for all beams of the multi-beam requires an enormous amount of time. On the other hand, if the blanking performance of all blankers is measured collectively, abnormalities in a small number of blankers cannot be detected. Even if only a few blankers are abnormal, writing accuracy may deteriorate depending on the writing method.

### PRIOR ART DOCUMENTS

### Patent Documents

[Patent Document 1] Japanese Unexamined Patent Publication No. 2017-073461

[Patent Document 2] Japanese Unexamined Patent Publication No. 2005-116743

[Patent Document 3] Japanese Unexamined Patent Publication No. 2020-119682

### SUMMARY OF THE INVENTION

It is an object of the present invention to provide an abnormality diagnosis method for a blanking aperture array substrate that can efficiently and accurately inspect abnormalities in blankers, and a multi-beam writing method that uses the results of the abnormality diagnosis.

According to one aspect of the present invention, there is provided an abnormality diagnosis method for a blanking aperture array substrate that uses a plurality of individual blankers to perform individual on/off control of beams corresponding to each of a plurality of beams. The method includes grouping the plurality of individual blankers into a plurality of groups and measuring blanking performance of the individual blankers for each of the groups, and dividing any group exhibiting abnormal blanking performance into a plurality of subgroups and measuring the blanking performance of the individual blankers for each of the subgroups.

According to one aspect of the present invention, there is provided multi-beam writing method including setting a beam corresponding to an individual blanker identified as having abnormal blanking performance by the method according to one aspect of the present invention as a defective beam, and writing a pattern on a substrate to be written using beams other than the defective beam.

### EFFECTS OF THE INVENTION

According to the present invention, abnormality diagnosis of the blankers can be efficiently and accurately performed.

### BRIEF DESCRIPTION OF THE DRAWINGS

FIG. 1 is a schematic diagram of a writing apparatus according to an embodiment of the present invention.

FIG. 2 is a schematic diagram of a patterned aperture array member.

FIG. 3 is a schematic diagram of a blanking aperture array substrate.

FIG. 4A is a diagram showing pixels obtained by dividing a writing area, and FIG. 4B is a diagram showing a beam array of a multi-beam.

FIG. 5 is a graph illustrating an example of on/off timing of a collective blanker and individual blankers.

FIG. 6 is a graph illustrating an example of on/off timing of a collective blanker and individual blankers.

FIG. 7 is a diagram illustrating a method for measuring the blanking performance of an individual blanker.

FIG. 8 is a flowchart illustrating an abnormality diagnosis method of a blanking aperture array substrate according to the embodiment.

FIG. 9A and FIG. 9B are graphs illustrating examples of comparison results of blanking performance measurements.

### DETAILED DESCRIPTION

The embodiments of the present invention will be described below with reference to the drawings. In the embodiments, a configuration using an electron beam as an example of a charged particle beam will be described. However, the charged particle beam is not limited to an electron beam and may be an ion beam or another type of charged particle beam.

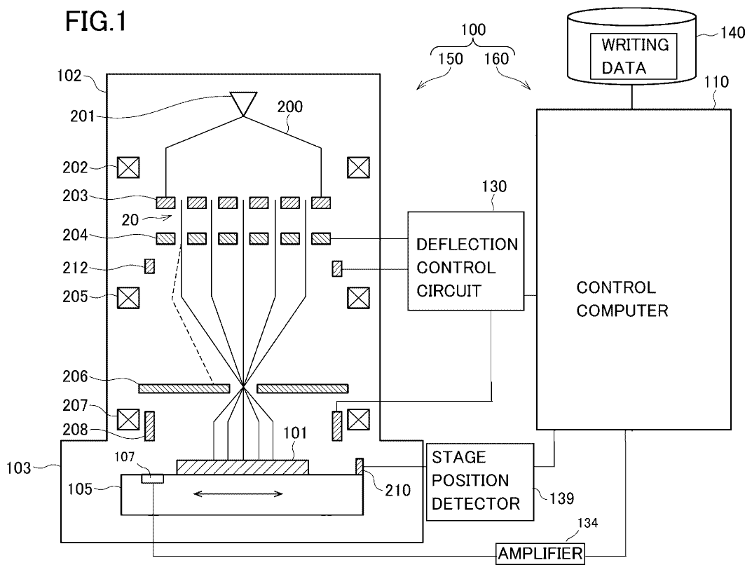

FIG. 1 is a schematic diagram of a writing apparatus according to an embodiment of the present invention. As shown in FIG. 1, the writing apparatus 100 includes a writing unit 150 and a control unit 160. The writing apparatus 100 is an example of a charged particle multi-beam writing apparatus. The writing unit 150 includes an electron column 102 and a writing chamber 103. Inside the electron column 102, an electron source 201, an illumination lens 202, a shaping aperture array member 203, a blanking aperture array substrate 204, a reduction lens 205, a collective blanking deflector (collective blanker) 212, a limiting aperture member 206, an objective lens 207, and a deflector 208 are arranged.

Inside the writing chamber 103, an XY stage 105 is arranged. A substrate 101 to be written is placed on the XY stage 105. The substrate 101 may be, for example, an exposure mask used for manufacturing a semiconductor device, or a semiconductor substrate (such as a silicon wafer) on which a semiconductor device is to be fabricated. The substrate 101 may also be a mask blank that is coated with a resist and has not yet been patterned. A mirror 210 for measuring the position of the XY stage 105 is also disposed on the XY stage 105.

The XY stage 105 is also provided with a detector 107 for detecting the beam current. The detector 107 is, for example, a Faraday cup. The beam current detection results obtained by the detector 107 are output to the control computer 110 via an amplifier 134.

The control unit 160 includes a control computer 110, a deflection control circuit 130, an amplifier 134, a stage position detector 139, a storage device 140, and the like. Writing data is input from an external source and stored in the storage device 140 (storage unit).

In FIG. 1, the components necessary for explaining the embodiment are shown. The writing apparatus 100 may also include other components that are normally required.

The electron beam 200 emitted from the electron source 201 (emission unit) illuminates the entire shaping aperture array member 203 substantially perpendicularly, as directed by the illumination lens 202.

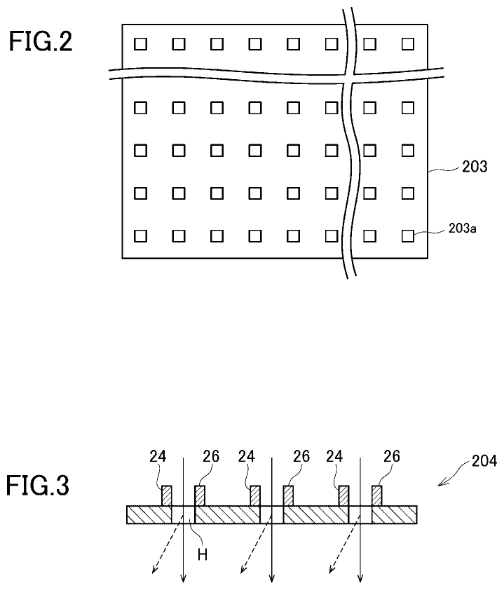

FIG. 2 is a schematic diagram of the shaping aperture array member 203. As shown in FIG. 2, the shaping aperture array member 203 has openings 203a arranged in an m-column (in the y-direction)×n-row (in the x-direction) matrix (m, n≥2) at a predetermined pitch. Each opening 203a is rectangular or circular, all having the same dimensions and shape. By allowing portions of the electron beam 200 to pass through the plurality of openings 203a, a multi-beam 20 is formed.

As shown in FIG. 3, through-holes (openings) H are formed in the blanking aperture array substrate 204 at positions corresponding to the openings 203a of the shaping aperture array member 203. Individual blankers, each including a pair of electrodes 24 and 26, are disposed in the respective through-holes H. One of the two electrodes 24 and 26 for each beam (for example, electrode 26) is fixed at a ground voltage, and by changing the voltage applied to the other electrode (for example, electrode 24), blanking control of each beam is performed.

In this manner, the plurality of individual blankers perform blanking deflection for the respective beams of the multi-beam that have passed through the corresponding openings 203a of the shaping aperture array member 203.

The multi-beam 20 that has passed through the blanking aperture array substrate 204 is reduced by the reduction lens 205 and directed toward the central hole formed in the limiting aperture member 206. Here, electron beams deflected by the individual blankers of the blanking aperture array substrate 204 are displaced from the central hole of the limiting aperture member 206 and blocked by the limiting aperture member 206. On the other hand, electron beams that are not deflected by the individual blankers of the blanking aperture array substrate 204 pass through the central hole of the limiting aperture member 206 unless they are deflected by the collective blanker 212.

The collective blanker 212 can perform collective blanking of the multi-beam. Since the collective blanker 212 only performs ON/OFF control, it can operate at a higher speed than the individual blankers on the blanking aperture array substrate 204.

Blanking control is performed by the combination of the ON/OFF states of the individual blankers and the ON/OFF state of the collective blanker 212, thereby controlling the ON/OFF states of the beams. In this manner, the limiting aperture member 206 blocks each beam that has been deflected into an OFF state by either the individual blankers or the collective blanker 212.

The multi-beam 20 that has passed through the limiting aperture member 206 is focused by the objective lens 207 to form a pattern image with a desired reduction ratio, and is collectively deflected in the same direction by the deflector 208 to be irradiated onto the substrate 101. When the XY stage 105 is continuously moving, the deflector 208 controls the beams so that the irradiation positions follow the movement of the XY stage 105. Ideally, the multi-beam 20 irradiated at one time is arranged at a pitch corresponding to the array pitch of the openings 203a of the shaping aperture array member 203 multiplied by the desired reduction ratio.

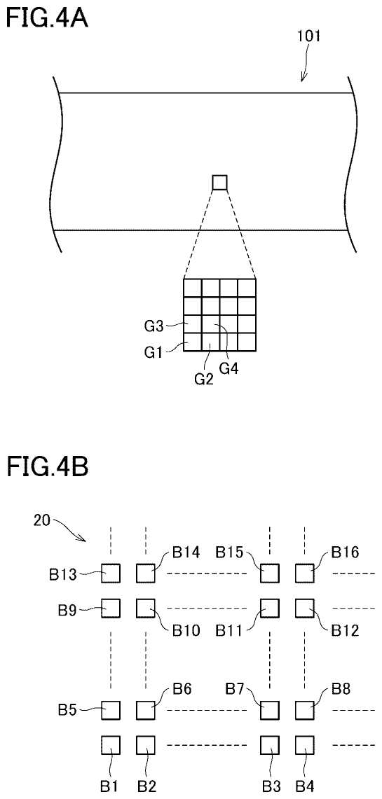

For example, in the writing process of the substrate 101, as shown in FIG. 4A, the writing area of the substrate 101 is divided into a plurality of mesh-shaped pixels G1, G2, G3, . . . , and the beams with the required exposure dose are irradiated onto each pixel to write a desired pattern. The pixel size is, for example, the size of a single individual beam.

In multi-beam writing, a plurality of beams are sequentially irradiated onto a single pixel on substrate 101 to provide the desired exposure dose. For example, for the pixel G1 shown in FIG. 4A, beams B1, B3, B9, and B11 in the multi-beam 20 shown in FIG. 4B are sequentially irradiated. For pixel G2, beams B2, B4, B10, and B12 are irradiated. For pixel G3, beams B5, B7, B13, and B15 are irradiated. For pixel G4, beams B6, B8, B14, and B16 are irradiated.

As described above, the writing apparatus 100 performs blanking control of each beam using both the ON/OFF control for individual blanking and the ON/OFF control for collective blanking that controls the entire multi-beam.

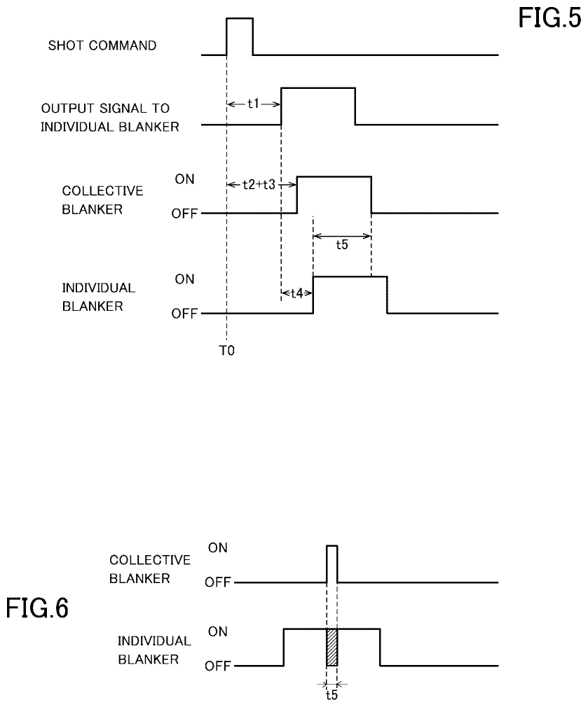

For example, as shown in FIG. 5, when a shot command is output from the control computer 110 at time T0, the deflection control circuit 130 outputs a voltage to the individual blankers of the blanking aperture array substrate 204. This voltage output process is performed after a variable delay time t1 has elapsed. The voltage output by this process is applied to the electrodes of the individual blankers after a delay time t4 due to the cable length, thereby setting the individual blankers to the beam ON state.

In addition, the deflection control circuit 130 outputs a voltage to the collective blanker 212 in response to the shot command, thereby causing the collective blanker 212 to be turned ON. After the time t2 required for digital-to-analog conversion of the shot command and a variable delay time t3 have elapsed, the collective blanker 212 is set to the beam ON state.

While the collective blanker 212 is in the beam ON state, the beams that have been set ON by the individual blankers pass through the limiting aperture member 206 and are irradiated onto the substrate for a period t5.

As described above, the collective blanker 212 can be operated at a high speed. Therefore, as shown in FIG. 6, the ON time of the collective blanker 212 can be made shorter than that of the individual blankers.

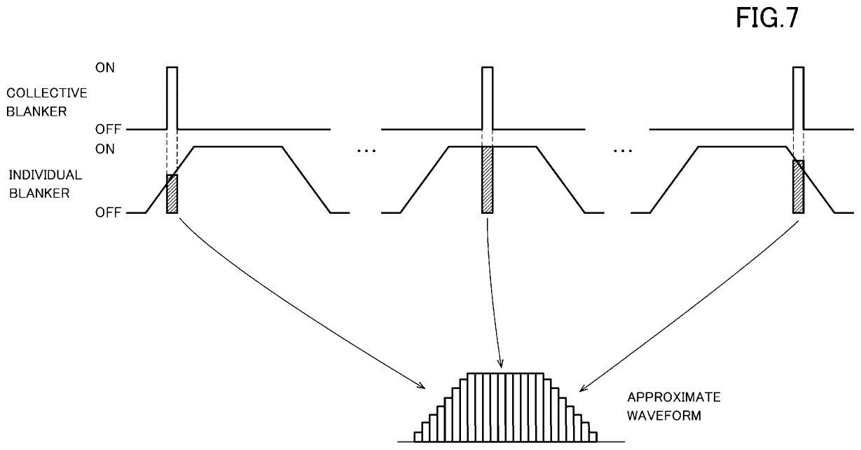

By changing the delay time t3, as shown in FIG. 7, the timing at which the collective blanker 212 turns ON can be shifted. The ON time of the collective blanker 212 is set to be extremely short relative to the ON time of the individual blankers, and while the ON timing of the collective blanker 212 is shifted, the beam current is detected by detector 107. By aligning the beam current detection results for each timing, a waveform approximating the output characteristics of the individual blankers (i.e., the change in the applied voltage of the individual blankers) can be obtained. The blanking performance of the individual blankers can be measured based on the time it takes for the obtained approximate output waveform to transition from the beam ON level to the beam OFF level (delay time), and the contribution of under-or over-irradiation to writing accuracy (the slope of the approximate output waveform from beam ON to beam OFF). Note that, instead of using the collective blanker 212, the measurement can also be performed by setting a very short predetermined measurement period at detector 107.

The shorter the beam ON time of the collective blanker 212, the smaller the detected value at the detector 107. Therefore, shots may be performed multiple times, and the average current per unit time may be calculated.

Since the blanking aperture array substrate 204 is provided with a large number of individual blankers, performing the blanking performance measurement described above for each individual blanker would require an enormous amount of time. Therefore, in this embodiment, several individual blankers are grouped, and the blanking performance is measured for each group. Groups exhibiting abnormalities are then subdivided into smaller groups, and the blanking performance is measured again.

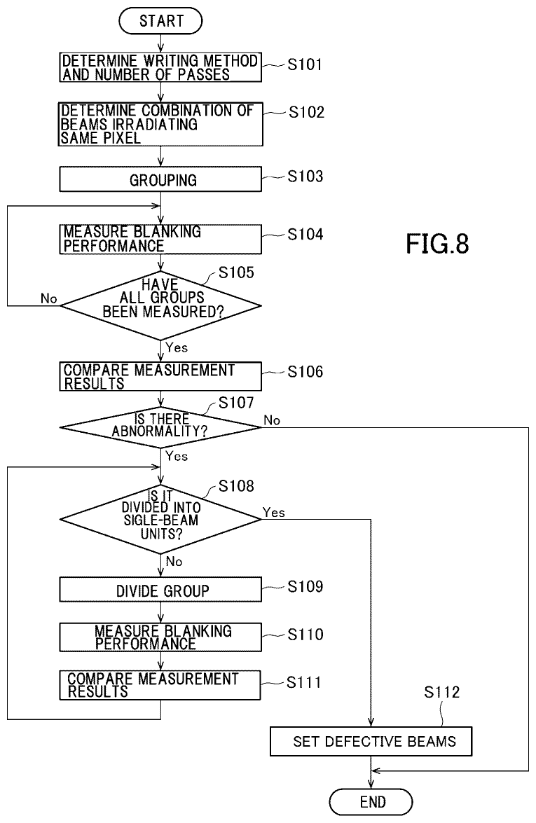

The method for diagnosing abnormalities in the blanking aperture array substrate will be described with reference to the flowchart shown in FIG. 8.

Determine the writing method for patterning the substrate and the number of passes for multi-pass writing (Step S101). This determines the combination of beams that will irradiate the same pixel in the writing area of the substrate (Step S102). For example, in the examples shown in FIGS. 4A and 4B, beams B1, B3, B9, and B11 are combined. Beams B2, B4, B10, and B12 are combined in the same manner, as are beams B5, B7, B13, and B15, and beams B6, B8, B14, and B16.

Based on the required inspection time, several of the beam combinations determined in Step S102 are grouped together (Step S103). For example, in the examples shown in FIGS. 4A and 4B, the individual blankers corresponding to beams B1, B3, B9, and B11, as well as those corresponding to beams B2, B4, B10, and B12, are grouped together. Similarly, the individual blankers corresponding to beams B5, B7, B13, and B15, and those corresponding to beams B6, B8, B14, and B16, are grouped together.

Measure the blanking performance of the individual blankers on a group-by-group basis for the groups formed in Step S103 (Step S104). For example, the method shown in FIG. 7 can be used to measure the blanking performance. That is, while performing ON/OFF control of the multiple individual blankers corresponding to the beams of the group being measured, the beam ON time of the collective blanker 212 is made extremely short and its ON timing is varied, and the beam current is detected by the detector 107. Using the detected beam current, an approximate waveform of the applied voltage representing the blanking performance of the grouped individual blankers can be obtained. Beams other than those in the group being measured are turned off.

Once the blanking performance has been measured for all groups (Step S105—Yes), the measurement results (approximate waveforms) of each group are compared, and groups exhibiting abnormal blanking performance are identified (Step S106).

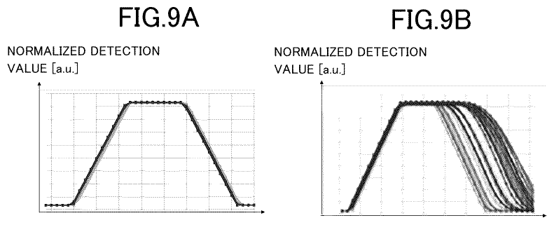

For example, as shown in FIG. 9A, when the measurement results of all groups match, it is determined that the blanking performance of all groups is normal (Step S107_No). On the other hand, as shown in FIG. 9B, a group whose measurement results behave differently from the other groups is determined to have abnormal blanking performance (Step S107_Yes).

The group determined to be abnormal is subdivided into multiple smaller groups, and the blanking performance of individual blankers is measured for each small group, with the measurement results compared. In this manner, the detection of abnormal groups, subdivision of the detected groups, and measurements are repeated until the unit of a single beam is reached (Steps S108-S111). In this way, individual blankers with abnormal blanking performance are detected, and the corresponding individual beams are set as defective beams (Step S112).

For example, if a group consisting of beams B1, B3, B9, B11 and B2, B4, B10, B12 is determined to have abnormal blanking performance, this group is divided into two subgroups: one consisting of beams B1, B3, B9, B11, and the other consisting of beams B2, B4, B10, B12.

The blanking performance of the two subgroups is measured, and if the subgroup consisting of beams B2, B4, B10, and B12 is found to be abnormal, it is further divided into individual beams. Then, the blanking performance is measured for each individual beam, and any individual blanker with abnormal performance is detected.

The detected defective beams are configured so as not to be used during pattern writing. If there are defective beams that are not used for writing, a known defect correction technique is applied.

Thus, in this embodiment, by grouping multiple individual blankers and measuring their blanking performance for each group, the diagnostic time can be reduced compared to measuring the blanking performance of all individual blankers one by one, and the abnormality inspection of individual blankers can be performed efficiently.

Moreover, groups exhibiting abnormal blanking performance are subdivided into subgroups (smaller groups), and measurements are repeated at the subgroup level the individual blankers with abnormalities are identified. Therefore, the abnormality inspection of individual blankers can be performed with high accuracy.

In the above embodiment, when comparing the measurement results obtained by measuring the blanking performance for each group, it is preferable to normalize the detected values at the optimal delay time.

Instead of comparing the measurement results for each group, it is also possible to calculate the leakage dose (or insufficient dose) caused by blanking abnormalities from the unnormalized measurement results, and determine whether an abnormality exists based on the effect of the dose deviation on the dimensions.

For example, if the value obtained by dividing the leakage dose (or insufficient dose) by the reference dose and multiplying by the dose latitude (a value indicating the change in line width with respect to dose variation) is equal to or greater than a predetermined threshold, it is determined that the blanking performance of the group is abnormal.

In the above embodiment, an example has been described in which beams that irradiate the same pixel are combined and several of these combinations are grouped together; however, the method of grouping is not limited to this. For example, the blanking aperture array substrate 204 may be divided into multiple regions, and the individual blankers in each region may be grouped. Groups (regions) with abnormal blanking performance can be further divided into smaller groups (regions) for further measurement.

In the above embodiment, a configuration has been described in which the beam ON time of the collective blanker 212 is made shorter than the beam ON time of the individual blankers, and the beam current is detected with the detector 107. However, instead of using the collective blanker 212, a high-speed, high-resolution current detector may be used to detect the beam current and measure the blanking performance of the individual blankers.

In the above embodiment, a configuration has been described in which the beam current of beams that were not blanked (i.e., turned ON) is detected by the detector 107 provided on the XY stage 105. However, the limiting aperture member 206 may be used as the detector. In this case, the beam current of the blanked beams can be detected.

While the present invention has been described in detail with reference to specific embodiments, it will be apparent to those skilled in the art that various modifications can be made without departing from the spirit and scope of the invention. This application is based on Japanese Patent Application No. 2023-199281 filed on Nov. 24, 2023, the entire contents of which are hereby incorporated by reference.

### DESCRIPTION OF REFERENCE SIGNS

20 Multi-beam

107 Detector

203 Shaping Aperture Array Member

204 Blanking Aperture Array Substrate

212 Collective Blanker

1. An abnormality diagnosis method for a blanking aperture array substrate that uses a plurality of individual blankers to perform individual on/off control of beams corresponding to each of a plurality of beams, the method comprising:
grouping the plurality of individual blankers into a plurality of groups and measuring blanking performance of the individual blankers for each of the groups; and
dividing any group exhibiting abnormal blanking performance into a plurality of subgroups and measuring the blanking performance of the individual blankers for each of the subgroups.

2. The method according to claim 1, wherein a step of measuring the blanking performance comprises:
setting the individual blankers of the group to be measured to beam-on;
setting a collective blanker, which is capable of blanking the plurality of beams at once, such that its beam-on time is shorter than the beam-on time of the individual blankers; and
during the beam-on setting of the individual blankers, varying the beam-on timing of the collective blanker, detecting beam currents of a plurality of beams corresponding to the group at each beam-on timing, and measuring the blanking performance of the individual blankers included in the group based on the detected beam currents.

3. The abnormality diagnosis method for a blanking aperture array substrate according to claim 1,
wherein each beam of the plurality of beams writes a pixel obtained by dividing a writing region of a substrate to be written into a mesh, and
wherein the blanking performance is measured by grouping individual blankers corresponding to a plurality of beams that perform multiple passes on the same pixel.

4. The method according to claim 1,
further comprising repeatedly dividing a group having abnormal blanking performance and measuring the blanking performance on a per-subgroup basis, and identifying an individual blanker having abnormal blanking performance.

5. A multi-beam writing method, comprising:
setting a beam corresponding to an individual blanker identified as having abnormal blanking performance by the method according to claim 4 as a defective beam; and
writing a pattern on a substrate to be written using beams other than the defective beam.

6. The method according to claim 1, wherein the measuring of the blanking performance includes obtaining an approximate waveform representing output characteristics of the individual blankers based on detected beam currents.

7. The method according to claim 6, wherein the blanking performance is evaluated based on a delay time for the approximate waveform to transition from a beam-on level to a beam-off level.

8. The method according to claim 6, wherein the blanking performance is evaluated based on a slope of the approximate output waveform from the beam-on level to the beam-off level as a contribution to under-irradiation or over-irradiation.

9. The method according to claim 1, further comprising normalizing detected values at an optimal delay time when comparing measurement results among the groups.

10. The method according to claim 1, further comprising determining whether abnormal blanking performance exists based on a leakage dose or an insufficient dose calculated from unnormalized measurement results.

11. The method according to claim 10, wherein it is determined that the blanking performance is abnormal when a value obtained by dividing the leakage dose or insufficient dose by a reference dose and multiplying by a dose latitude is equal to or greater than a predetermined threshold.

12. The method according to claim 1, wherein the individual blankers are grouped based on a plurality of beams that perform multiple-pass writing of a same pixel in a writing region.

13. The method according to claim 1, wherein the blanking aperture array substrate is divided into a plurality of regions, and the individual blankers are grouped for each region.

14. The method according to claim 2, wherein shots are performed multiple times and an average beam current per unit time is calculated.
